(19) United States
(12) Patent Application Publication
(10) Pub. No.: US 2012/0032683 A1
(43) Pub. Date: Feb. 9, 2012

(54) METHOD FOR DIAGNOSING CURRENT SENSORS IN AN INDUCTION MACHINE DURING OPERATION THEREOF

(75) Inventors: Andreas Greif, Neunkirchen/Brand (DE); Bernhard Wagner, Nuernberg (DE)

(73) Assignee: CONTI TEMIC MICROELECTRONIC GMBH, Nuernberg (DE)

(21) Appl. No.: 13/258,896

(22) PCT Filed: Jul. 12, 2010
(86) PCT No.: PCT/EP10/59996

§ 371 Date: Sep. 22, 2011

(30) Foreign Application Priority Data
Jul. 24, 2009 (DE) 10 2009 034 595.7

(51) Int. Cl. G01R 31/02

(52) U.S. Cl. 324/537

(57) ABSTRACT

A method diagnoses current sensors of an n-phase induction machine which has n−1 current sensors. The n phases of the induction machine are short-circuited for a brief period of time during normal operation of the induction machine, and the time progressions of the n−1 currents are measured by the n−1 current sensors during the short-circuit operation. The actual values of the time progressions of the n−1 measured short-circuit currents are compared to corresponding prescribed target values for the n−1 short-circuit currents. A potential fault state of one or more current sensors is determined from the comparison.

The invention relates to a method for diagnosing current sensors of an n-phase induction machine having n−1 current sensors during operation thereof.

Controlling electric induction machines, for example in order to use them as a drive mechanism in vehicles, requires, among other things, current sensors in order to detect the phase currents. In this context, an n-phase induction machine requires at least n−1 current sensors in order to detect all phase currents. For a conventional 3-phase induction machine, this means, for example, that two current sensors are provided for two phases of the 3-phase induction machine. From the n−1 phase currents measured, it is possible to determine the nth phase current since the sum of the phase currents of an induction machine always has the value of zero at any time. In this context, it is required to monitor the current sensor system during operation with the aim of performing a recalibration, which may be necessary, of current sensors or identifying a defective current sensor.

If faults occur in current sensors such as, for example, offset errors, gain errors, line breaks or short circuits, a wrong torque of the induction machine can be generated as a consequence thereof. The unwanted effects of wrong torques due to sensor faults can be, for example, a swinging torque, noise generation and vibrations, but also danger to persons due to unwanted or excessive acceleration or delay when using an induction machine as drive mechanism in a vehicle.

An approach for diagnosing current sensors known from the prior art is to use, in addition to the n−1 current sensors needed at the least for the purpose of control, a further current sensor so that all phases of an induction machine can be monitored. For example, a third current sensor is provided in a 3-phase induction machine.

Disadvantageous in this arrangement are the increased costs. Since the sum of all phase streams must always be equal to zero in an n-phase induction machine, all currents are measured and it is checked whether the sum of the n current sensor signals in the case described is equal to zero, taking into account a suitable predetermined tolerance. In this manner, a single current sensor fault can be detected. In this context, however, it is not possible in every case to determine which of the current sensors is defective. Recalibration of a sensor is also not possible by means of this method.

It is the object of the present invention to specify a method for diagnosing current sensors of an n-phase induction machine having n−1 current sensors during the operation thereof, in which the disadvantages mentioned are avoided.

The object is achieved by a method as claimed in claim 1. Embodiments and developments of the concept of the invention are the subject matter of subclaims.

The object is achieved, in particular, by a method for diagnosing current sensors of an n-phase indication machine having n−1 current sensors, wherein the n phases of the induction machine are short-circuited for a brief period of time during normal operation of the induction machine and the variations in time of the n−1 currents are measured by the n−1 current sensors during the short-circuit operation. The actual values of the variations in time of the n−1 measured short-circuit currents are compared with corresponding predetermined target values for the n−1 short-circuit currents. A possible fault state of one or more current sensors is determined from the comparison.

In the text which follows, the invention will be explained in greater detail with reference to the exemplary embodiments shown in the figures of the drawings, identical elements being provided with identical reference symbols. In the drawings:

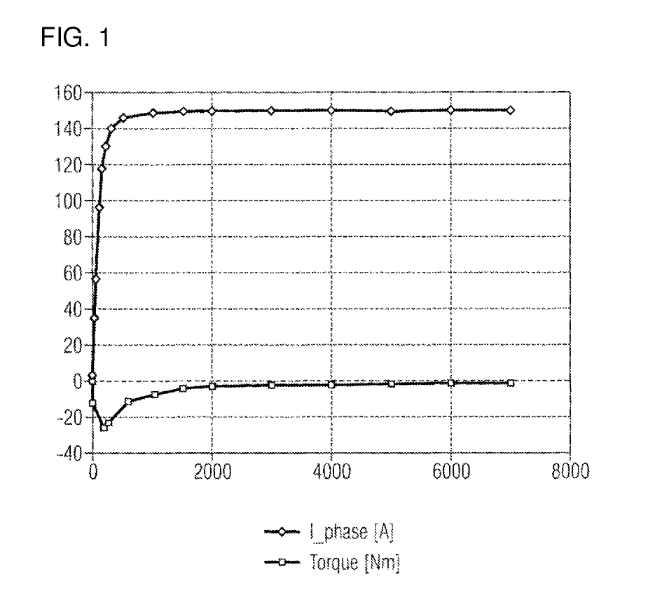

FIG. 1 shows in a diagram speed-dependent currents and short-circuit torques of a short-circuit induction machine;

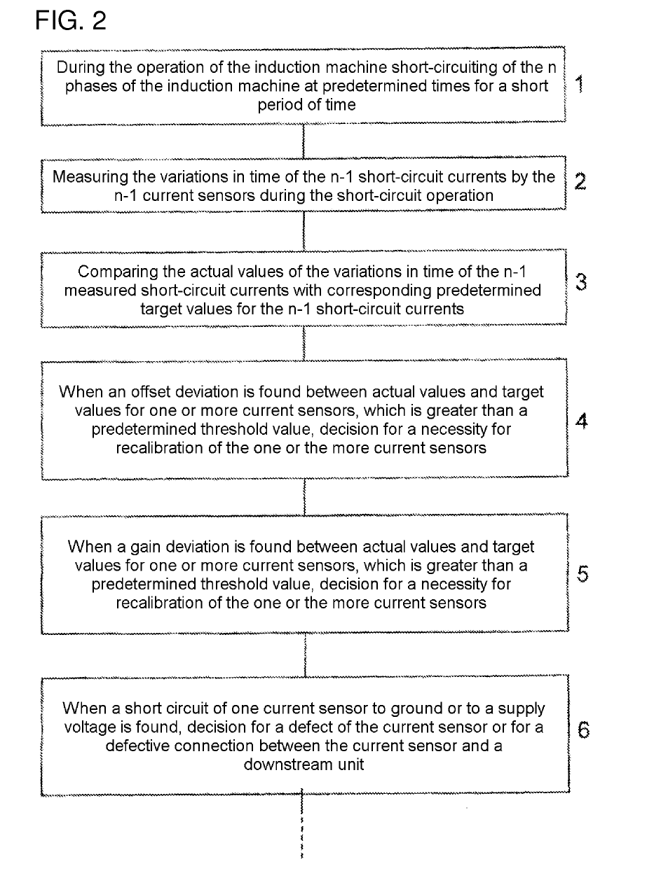

FIG. 2 shows in a flowchart an embodiment of the method according to the invention; and

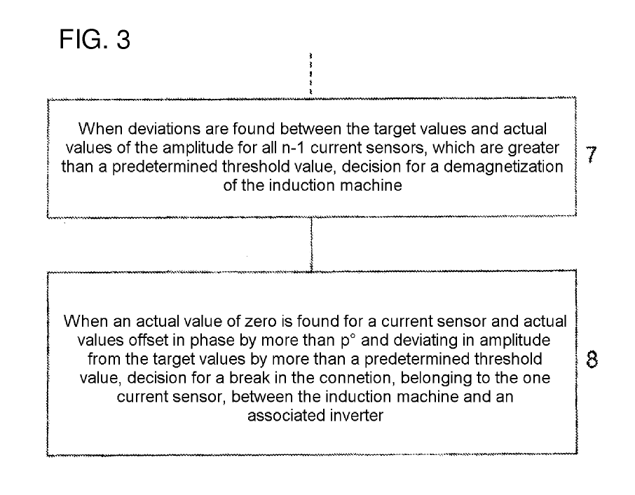

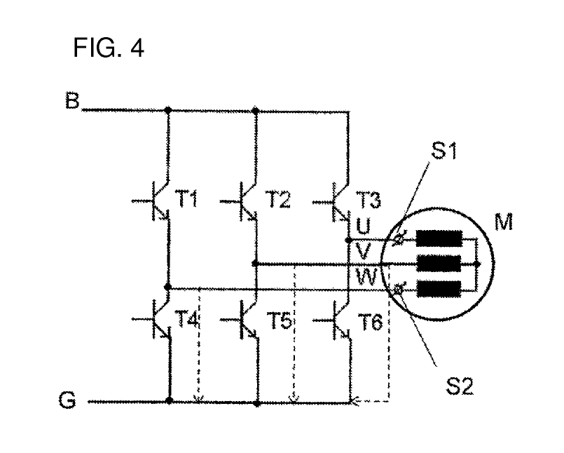

FIG. 3 shows an example of a drive inverter for a three-phase motor M having current sensors and a BE bridge circuit.

FIG. 1 shows in a diagram speed-dependent currents and short-circuit torques of a short-circuited induction machine constructed as permanent-field synchronous machine. If the terminals of an excited synchronous machine are short-circuited and it is actuated (for example during coasting of the motor due to centrifugal masses), speed-dependent currents will flow through the phases due to the induced voltage. In addition, a short-circuit torque of small amount is acting. FIG. 1 shows an exemplary progression of this. The x-axis of FIG. 1 designates the rotational speed in rpm, the y axis designates the amplitude of the measured phase current in amperes and, respectively, the torque in Nm.

The variation of the measured phase current with respect to the rotational speed is shown in the upper curve of FIG. 1, the variation of the torque is shown in the lower curve in FIG. 1. It can be seen that the magnitude of the measured phase current is very constant over a wide range of rotational speed above about 2000 rpm if the rotational speed is constant with time during the measurement. Similarly, the measured short-circuit torque is essentially constant over a wide range of rotational speed above about 2000 rpm.

If then the phase currents of an induction machine, of which it is known that it and its correctly calibrated current sensors operate correctly, are determined in short-circuit operation, the measured values can be used as reference values for diagnosing the current sensors of this or other similar induction machines. During this process, a particular range of tolerances can also be predetermined for the values determined in each case, within which these may deviate from the reference values without a defect of the current sensor or an incorrect operation being derived from. Certain fluctuations of the value determined for similarly produced induction machines can be obtained, for example, from component tolerances and manufacturing tolerances.

To check current sensors during the active operation of an induction machine, the induction machine is placed for a (very) short period of time, for example 3 to 6 periods of fundamental oscillation, into a short-circuit mode out of a normal mode of operation and, following this, back into normal operation. During this short period of time of short-circuit operation, the induction machine cannot be operated with a delivery of torque. The measuring method can be easily applied in an exemplary operation of an electric motor in a hybrid drive mechanism for a vehicle since, in this application, a drive mechanism frequently does not need to provide any torque. In all these cases, it is preferably provided that the transitions from normal operation to short-circuit operation and conversely are carried out without jerks. This can be implemented, for example, by means of a corresponding control system which can be arranged in hardware or software or a mixture of both.

In the text which follows, it is described which fault states of current sensors of an n-phase induction machine can be determined by measuring the short-circuit current and comparing it with reference values.
1. When an offset deviation between actual values and target values for one or more current sensors is found which is greater than a predetermined threshold value, this points to a necessity for recalibration of one or more of the current sensors.
2. When a gain deviation between actual values and target values for one or more current sensors is found which is greater than a predetermined threshold value, this points to a necessity for recalibration of one or more of the current sensors.
3. When a short-circuit of a current sensor to ground or to a supply voltage is found, this points to a defect of the current sensor or to defective connection between the current sensor and a downstream unit.
4. When deviations are found between the target values and actual values for all n−1 current sensors, which are greater than a predetermined threshold value, this points to a demagnetization of the induction machine.
5. When an actual value of zero is found for a current sensor and when actual values offset in phase by a particular value and deviating in amplitude by more than a predetermined value from the target values are found for all other current sensors, this points to an interruption of the connection, belonging to a current sensor, between the induction machine and an associated inverter.

FIG. 2 shows in a flowchart an embodiment of the method according to the invention for diagnosing current sensors of an n-phase induction machine having at least n−1 current sensors during operation thereof. For the considerations following, however, it is assumed that these are n−1 current sensors. In a first step 1, the n phases of the induction machine are short-circuited for a brief period of time cyclically at predetermined times at a constant rotational speed of the induction machine. In a step 2, the variations in time of the n−1 short-circuit currents through the n−1 current sensors are measured during the short-circuit operation. In a step 3, the actual values of the variations in time of the n−1 measured short-circuit currents are compared with corresponding predetermined target values for the n−1 short-circuit currents.

When an offset deviation is found between actual and target values for at least one of the current sensors which is greater than a predetermined threshold value, the necessity for recalibration of one or more of the current sensors is recognized in a step 4. In a step 5, when a gain deviation between actual values and target values is found for at least one of the current sensors which is greater than a predetermined threshold value, the necessity for recalibration of the at least one current sensor is decided. In a step 6, a defect of the current sensor or a defective connection between the current sensor and a downstream unit is decided when a short-circuit of a current sensor to ground or to a supply voltage is found.

In a step 7, a demagnetization of the induction machine is recognized when deviations between the target values and actual values of the amplitude are found for all n−1 current sensors which are greater than a predetermined threshold value. In a step 8, when an actual value of zero is found for a current sensor and when actual values offset in a phase by a certain value and deviating in amplitude by more than a predetermined value for the target values are found for all other current sensors, an interruption of the connection, belonging to a current meter, between the induction machine and an associated inverter is decided.

If the speed of the induction machine fluctuated by more than a predetermined threshold value during a short-circuit operation, the measured actual values are discarded and a new measurement and evaluation is carried out at the next time of a short-circuit operation. The order of method steps 4 to 8 is not mandatorily that shown in FIG. 2. In general, the method steps 4 to 8 can be carried out in any order.

In a preferred embodiment of the method, the findings of deviations between target values and actual values are carried out in order with decreasing statistical probability of the occurrence of the deviations. In this manner, the faults occurring statistically most probably are checked first in order to implement the method as efficiently as possible in time.

With the short-circuiting, the drive inverter usually present in any case (particularly its electronic switches) or other, particularly electronic switches in the feed circuit of the motor can be used. In this respect, FIG. 3 shows a simplified example of a drive inverter for a 3-phase motor M, which, in consequence, has three feed lines U, V, W of which two U, W are provided with a current sensor S1 and S2. The drive inverter comprises, among other things, a so-called BE bridge circuit having 6 electronic switches (in the form of transistors) T1 to T6 such as, e.g. IGBTs, MOSFETs etc. From the respective terminal of the motor M, three switches T4, T5, T6 lead to ground G and three switches T1, T2, T3 lead to supply potential B. For the purpose of short-circuiting, switches T4, T5, T6 are switched through and switches T1, T2, T3 are opened (or conversely, respectively).

1-10. (canceled)

11. A method for diagnosing n−1 current sensors in a feed circuit of an n-phase induction machine, which comprises the steps of:
during an operation of the n-phase induction machine, short-circuiting the n phases of the induction machine for a brief period of time at predetermined times;
measuring variations in time of n−1 short-circuit currents through the n−1 current sensors during a short-circuit operation; and
comparing actual values of the variations in time of the n−1 short-circuit currents measured with corresponding predetermined target values for the n−1 short-circuit currents.

12. The method according to claim 11, wherein when an offset deviation between the actual values and the predetermined target values is found for at least one of the current sensors, which is greater than a predetermined threshold value, a necessity for recalibration of at least one of the current sensors is decided.

13. The method according to claim 11, wherein when a gain deviation between the actual values and the predetermined target values is found for at least one of the current sensors, which is greater than a predetermined threshold value, a necessity for recalibration of at least one of the current sensors is decided.

14. The method according to claim 11, wherein when a short circuit of a current sensor to one of ground or to a supply voltage is found, one of a defect of the current sensor or a defective connection between the current sensor and a downstream unit is decided.

15. The method according to claim 11, wherein when deviations are found between the predetermined target values and the actual values of an amplitude for all of the n−1 current sensors, which are greater than a predetermined threshold value, a demagnetization of the n-phase induction machine is decided.

16. The method according to claim 11, wherein when an actual value of zero is found for a current sensor and when the actual values offset in phase by a particular first threshold value and deviating in amplitude by more than a predetermined second threshold value from the predetermined target values are found for all others of the current sensors, an interruption of the connection, belonging to the current sensor, between the n-phase induction machine and an associated inverter is decided.

17. The method according to claim 11, which further comprises carrying out a transition from a normal operation to the short-circuit operation and conversely without jerks by a control system for the n-phase induction machine.

18. The method according to claim 11, which further comprises discarding the actual values measured and not using them for comparison with corresponding ones of the target values if a rotational speed of the n-phase induction machine fluctuates by more than a predetermined threshold value during the short-circuit operation.

19. The method according to claim 11, wherein the n-phase induction machine is a part of a hybrid drive mechanism for a vehicle.

20. The method according to claim 11, which further comprises carrying out findings of deviations between the predetermine target values and the actual values in an order with decreasing statistical probability of an occurrence of the deviations.
